(19) United States
(12) Patent Application Publication
(10) Pub. No.: US 2026/0354120 A1
(43) Pub. Date: Nov. 5, 2026

(54) PROCESSES AND STRUCTURES FOR REWORKABLE DIRECT BONDING

(71) Applicant: ADEIA SEMICONDUCTOR BONDING TECHNOLOGIES INC., San Jose, CA (US)

(72) Inventors: Cyprian Emeka Uzoh, San Jose, CA (US); Rajan Gangadharan, San Jose, CA (US); Dominik Suwito, San Jose, CA (US); Thomas Workman, San Jose, CA (US)

(21) Appl. No.: 19/197,798

(22) Filed: May 2, 2025

(51) Int. Cl. H10P 74/00; H10W 72/00; H10W 80/00; H10W 90/00; H10W 90/20; H10W 95/00

(52) U.S. Cl. CPC H10P 74/23; H10W 90/00; H10W 72/019; H10W 80/016; H10W 80/041; H10W 80/312; H10W 80/327; H10W 90/20; H10W 90/792; H10W 90/794; H10W 95/00

(57) ABSTRACT

Disclosed herein are methods of forming a stack of microelectronic elements. In some implementations, the method includes directly bonding a first microelectronic element to a host surface at a first bond interface to form an initial bonded structure, inspecting the first bond interface for bonding defects, initially annealing the initial bonded structure if no critical bonding defect is detected, directly bonding a second microelectronic element over the first microelectronic element after initially annealing to form a stack, and annealing the stack. The method further includes debonding the first microelectronic element from the first bond interface if at least one or more bonding defects are detected, and cleaning the host surface after the first microelectronic element has been debonded. The method further includes repeating a stacking of microelectronic elements until a desired number of microelectronic elements are stacked together.

### BACKGROUND

### Field

This disclosure relates to semiconductor device structures and methods. In particular, some implementations are directed to structures and methods for directly bonding, inspecting, conditionally debonding and repairing semiconductor elements, such as stacked dies.

### Related Art

The approaches described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

Stacking semiconductor elements, which can be done with direct bonding, can provide many benefits. However, critical defects (e.g., killer defects) can arise when bonding semiconductor elements, such as semiconductor wafers or integrated device dies, as well as active and passive components fabricated in other materials other than silicon, such as silicon carbide, RF (Radio Frequency) substrates and diamond, amongst others, over a given substrate. These critical defects not only reduce device manufacturing yield but also further complicates manufacturing operations and decisions when wafers or dies have to be stacked on wafers or dies with critical defects. In practice, dummy non-functional dies may be stacked over bonder dies with a critical defect. Such use of dummy dies represents a loss of valuable real estate on a substrate. The penalty can be higher for hybrid bonded large dies, because large dies occupy a larger surface area of the substrate and the surface area of the substrate can accommodate fewer large dies compared to smaller dies.

Accordingly, there remains a need for methods to repair bonded dies having critical defects before subsequent higher temperature processing of the bonded assembly.

### BRIEF DESCRIPTION OF THE DRAWINGS

These and other features, aspects, and advantages of the disclosure are described with reference to drawings of certain implementations, which are intended to illustrate, but not to limit, the present disclosure. It is to be understood that the accompanying drawings, which are incorporated in and constitute a part of this specification, are for the purpose of illustrating concepts disclosed herein and may not be to scale.

FIGS. 1A and 1B schematically illustrate cross-sectional side views of first and second elements, prior to and after, respectively, a process for forming a directly bonded structure, and more particularly a hybrid bonded structure, according to various implementations of the present disclosure.

FIG. 2 is a schematic side cross section illustrating multiple types of bonded stacks.

FIG. 3 is a flowchart illustrating an example process of repairing and/or forming a bonded structure, according to various implementations of the present disclosure.

FIGS. 4A-4O are schematic side cross-sectional views of an example bonded structure at various blocks of the process shown in FIG. 3, according to various implementations of the present disclosure.

FIG. 5 is a schematic cross section of an example bonded structure, according to various implementations of the present disclosure.

FIG. 6 is a schematic side view of an intermediate bonded structure prior to final anneal, having similar bond strengths at interfaces throughout the stack.

FIG. 7 is a schematic side view of an intermediate bonded structure prior to final anneal completed by process shown in FIG. 3, having different bond strengths at different interfaces according to various implementations of the present disclosure.

### DETAILED DESCRIPTION

Although several implementations, examples, and illustrations are disclosed below, it will be understood by those of ordinary skill in the art that the devices, systems, and methods described herein extend beyond the specifically disclosed implementations, examples, and illustrations and includes other uses of the devices, systems, and methods and obvious modifications and equivalents thereof. Implementations are described with reference to the accompanying figures, wherein like numerals refer to like elements throughout. The terminology used in the description presented herein is not intended to be interpreted in any limited or restrictive manner simply because it is being used in conjunction with a detailed description of some specific implementations of the devices, systems, and methods. In addition, implementations can comprise several novel features. No single feature is solely responsible for its desirable attributes or is essential to practicing the devices, systems, and methods herein described.

The present disclosure may be understood by reference to the following detailed description. It is noted that, for purposes of illustrative clarity, certain elements in various drawings may not be drawn to scale, may be represented schematically or conceptually, or otherwise may not correspond exactly to certain physical configurations of implementations.

### Direct Bonding

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical or optical communication to the other element.

In various embodiments, the bonding layers 108a and/or 108b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride, or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564, filed Jun. 30, 2023, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Many organic adhesives lack strong chemical or covalent bonds with either element. In such processes, the connections between the elements are weak and/or readily reversed, such as by reheating.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In one example conventional metal bonding process, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

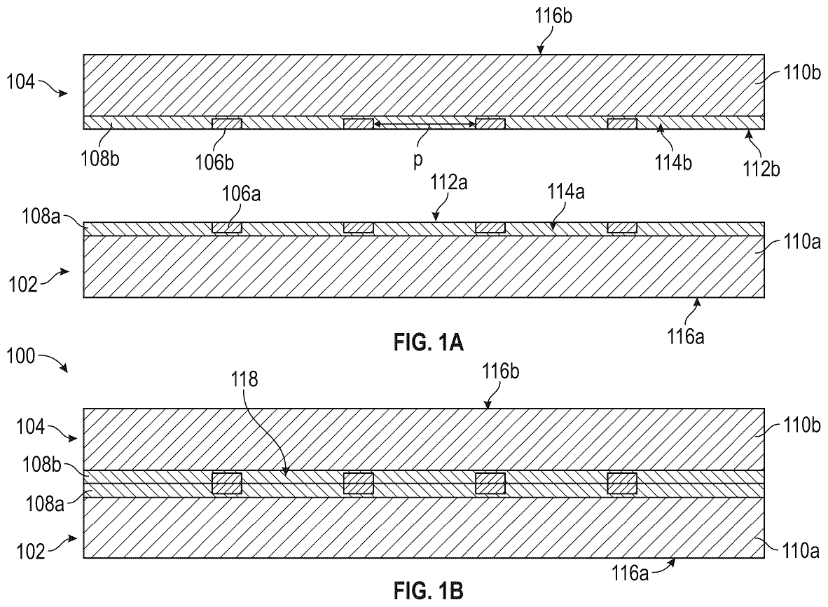

FIGS. 1A and 1B schematically illustrate cross-sectional side views of first and second elements 102, 104 prior to and after, respectively, a process for forming a directly bonded structure, and more particularly a hybrid bonded structure, according to some embodiments. In FIG. 1B, a bonded structure 100 comprises the first and second elements 102 and 104 that are directly bonded to one another at a bond interface 118 without an intervening adhesive. Conductive features 106a of a first element 102 may be electrically connected to corresponding conductive features 106b of a second element 104. In the illustrated hybrid bonded structure 100, the conductive features 106a are directly bonded to the corresponding conductive features 106b without intervening solder or conductive adhesive.

The conductive features 106a and 106b of the illustrated embodiment are embedded in, and can be considered part of, a first bonding layer 108a of the first element 102 and a second bonding layer 108b of the second element 104, respectively. Field regions of the bonding layers 108a, 108b extend between and partially or fully surround the conductive features 106a, 106b. The bonding layers 108a, 108b can comprise layers of non-conductive materials suitable for direct bonding, as described above, and the field regions are directly bonded to one another without an adhesive. The non-conductive bonding layers 108a, 108b can be disposed on respective front sides 114a, 114b of base substrate portions 110a, 110b.

The first and second elements 102, 104 can comprise microelectronic elements, such as semiconductor elements, including, for example, integrated device dies, wafers, passive devices, discrete active devices such as power switches, MEMS, optical devices (e.g., emitters, sensors, waveguides, interposers, transducers, switches, transceivers), etc. In some embodiments, the base substrate portion can comprise a device portion, such as a bulk semiconductor (e.g., silicon) portion of the elements 102, 104, and back-end-of-line (BEOL) interconnect layers over such semiconductor portions. The bonding layers 108a, 108b can be provided as part of such BEOL layers during device fabrication, as part of redistribution layers (RDL), or as specific bonding layers added to existing devices, with bond pads extending from underlying contacts. Active devices and/or circuitry (not shown) can be patterned and/or otherwise disposed in or on the base substrate portions 110a, 110b, and can electrically communicate with at least some of the conductive features 106a, 106b. Active devices and/or circuitry can be disposed at or near the front sides 114a, 114b of the base substrate portions 110a, 110b, and/or at or near opposite backsides 116a, 116b of the base substrate portions 110a, 110b. In other embodiments, one or both of the elements 102, 104 may not include active circuitry, but may instead comprise dummy elements, passive interposers, passive optical elements (e.g., glass substrates, gratings, lenses), etc. The bonding layers 108a, 108b are shown as being provided on the front sides of the elements, but similar bonding layers can be additionally or alternatively provided on the back sides of the elements.

In some embodiments, the base substrate portions 110a, 110b can have significantly different coefficients of thermal expansion (CTEs), and bonding elements that include such different based substrate portions can form a heterogenous bonded structure. The CTE difference between the base substrate portions 110a and 110b, and particularly between bulk semiconductor (typically single crystal) portions of the base substrate portions 110a, 110b, can be greater than 5 ppm/° C. or greater than 10 ppm/° C.. For example, the CTE difference between the base substrate portions 110a and 110b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 110a, 110b can comprise optoelectronic single crystal materials, including perovskite materials, that are useful for optical piezoelectric or pyroelectric applications, and the other of the base substrate portions 110a, 110b comprises a more conventional substrate material. For example, one of the base substrate portions 110a, 110b comprises lithium tantalate (LiTaO3) or lithium niobate (LiNbO3), and the other one of the base substrate portions 110a, 110b comprises silicon (Si), quartz, fused silica glass, sapphire, or a glass. In other embodiments, one of the base substrate portions 110a, 110b comprises a III-V single semiconductor material, such as gallium arsenide (GaAs) or gallium nitride (GaN), and the other one of the base substrate portions 110a, 110b can comprise a non-III-V semiconductor material, such as silicon (Si), or can comprise other materials with similar CTE, such as quartz, fused silica glass, sapphire, or a glass. In still other embodiments, one of the base substrate portions 110a, 110b comprises a semiconductor material and the other of the base substrate portions 110a, 110b comprises other materials, such as a glass, organic, ceramic substrate, or an optical component.

In some arrangements, the first element 102 can comprise a singulated element, such as a singulated integrated device die. In other arrangements, the first element 102 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate (e.g., a laminate substrate, a ceramic substrate, etc.) or a passive or active interposer. Similarly, the second element 104 can comprise a singulated element, such as a singulated integrated device die. In other arrangements, the second element 104 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding layers for both bonded and singulated elements can be coextensive, and may include markings indicative of the common singulation process for the bonded structure (e.g., saw markings if a saw singulation process is used).

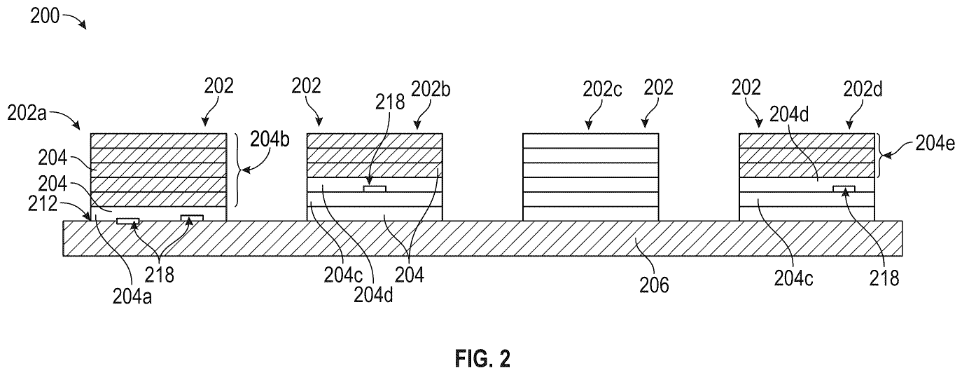

While only two elements 102, 104 are shown, any suitable number of elements can be stacked in the bonded structure 100, as discussed in more detail with respect to FIGS. 2-7 below. For example, a third element (not shown) can be stacked on the second element 104, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 102. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer. Typically stacks of multiple elements are not annealed until the last element to be directly bonded is bonded at room temperature, in order to avoid subjecting lower elements of the stack to multiple anneals.

To effectuate direct bonding between the bonding layers 108a, 108b, the bonding layers 108a, 108b can be prepared for direct bonding. Non-conductive bonding surfaces 112a, 112b at the upper or exterior surfaces of the bonding layers 108a, 108b can be prepared for direct bonding by polishing, for example, by chemical mechanical polishing (CMP). The roughness of the polished bonding surfaces 112a, 112b can be less than 30 Å rms. For example, the roughness of the bonding surfaces 112a and 112b can be in a range of about 0.1 Å rms to 15 Å rms, 0.5 Å rms to 10 Å rms, or 1 Å rms to 5 Å rms. Polishing can also be tuned to leave the conductive features 106a, 106b recessed relative to the field regions of the bonding surfaces 112a, 112b.

Preparation for direct bonding can also include cleaning and exposing one or both of the bonding surfaces 112a, 112b to a plasma and/or etchants to activate at least one of the surfaces 112a, 112b. In some embodiments, one or both of the surfaces 112a, 112b can be terminated with a species after activation or during activation (e.g., during the plasma and/or etch processes). Without being limited by theory, in some embodiments, the activation process can be performed to break chemical bonds at the bonding surface(s) 112a, 112b, and the termination process can provide additional chemical species at the bonding surface(s) 112a, 112b that alters the chemical bond and/or improves the bonding energy during direct bonding. In some embodiments, the activation and termination are provided in the same step, e.g., a plasma to activate and terminate the surface(s) 112a, 112b. In other embodiments, one or both of the bonding surfaces 112a, 112b can be terminated in a separate treatment to provide the additional species for direct bonding. In various embodiments, the terminating species can comprise nitrogen. For example, in some embodiments, the bonding surface(s) 112a, 112b can be exposed to a nitrogen-containing plasma. Other terminating species can be suitable for improving bonding energy, depending upon the materials of the bonding surfaces 112a, 112b. Further, in some embodiments, the bonding surface(s) 112a, 112b can be exposed to fluorine. For example, there may be one or multiple fluorine concentration peaks at or near a bond interface 118 between the first and second elements 102, 104. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 100, the bond interface 118 between two non-conductive materials (e.g., the bonding layers 108a, 108b) can comprise a very smooth interface with higher nitrogen (or other terminating species) content and/or fluorine concentration peaks at the bond interface 118. In some embodiments, the nitrogen and/or fluorine concentration peaks may be detected using various types of inspection techniques, such as SIMS techniques. The polished bonding surfaces 112a and 112b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially smooths out high points on the bonding surface.

The non-conductive bonding layers 108a and 108b can be directly bonded to one another without an adhesive. In some embodiments, the elements 102, 104 are brought together at room temperature, without the need for application of a voltage, and without the need for application of external pressure or force beyond that used to initiate contact between the two elements 102, 104. Contact alone can cause direct bonding between the non-conductive surfaces of the bonding layers 108a, 108b (e.g., covalent dielectric bonding). Subsequent annealing of the bonded structure 100 can cause the conductive features 106a, 106b to directly bond.

In some embodiments, prior to direct bonding, the conductive features 106a, 106b are recessed relative to the surrounding bonding surfaces, such that a total gap between opposing contacts after dielectric bonding and prior to anneal is less than 15 nm, or less than 10 nm. Because the recess depths for the conductive features 106a and 106b can vary across each element, due to process variation, the noted gap can represent a maximum or an average gap between corresponding conductive features 106a, 106b of two joined elements (prior to anneal). Upon annealing, the conductive features 106a and 106b can expand and contact one another to form a metal-to-metal direct bond.

During annealing, the conductive features 106a, 106b (e.g., metallic material) can expand while the direct bonds between surrounding non-conductive materials of the bonding layers 108a, 108b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials' melting temperature. In various embodiments, bonds can form at lower temperatures compared to soldering or thermocompression bonding.

In various embodiments, the conductive features 106a, 106b can comprise discrete pads, contacts, electrodes, or traces at least partially embedded in the non-conductive field regions of the bonding layers 108a, 108b. In some embodiments, the conductive features 106a, 106b can comprise exposed contact surfaces of TSVs (e.g., through silicon vias).

As noted above, in some embodiments, in the elements 102, 104 of FIG. 1A prior to direct bonding, portions of the respective conductive features 106a and 106b can be recessed below the non-conductive bonding surfaces 112a and 112b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 106a, 106b or to average depths of the recesses relative to local non-conductive field regions. Even for an individual conductive feature 106a, 106b, the vertical recess can vary across the surface of the feature, and can be measured at or near the lateral middle or center of the cavity in which a given conductive feature 106a, 106b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 106a, 106b across the direct bond interface 118 (e.g., small or fine pitches for regular arrays).

In some embodiments, a pitch p of the conductive features 106a, 106b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 106a and 106b to one of the lateral dimensions (e.g., a diameter) of the conductive feature is less than 20, or less than 10, or less than 5, or less than 3 and sometimes desirably less than 2. In various embodiments, the conductive features 106a and 106b and/or traces can comprise copper or copper alloys, although other metals may be suitable, such as nickel, aluminum, or alloys thereof. The conductive features disclosed herein, such as the conductive features 106a and 106b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 102, 104, as shown, the orientations of one or more conductive features 106a, 106b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 106b in the bonding layer 108b (and/or at least one internal conductive feature, such as a BEOL feature) of the upper element 104 may be tapered or narrowed upwardly, away from the bonding surface 112b. By way of contrast, at least one conductive feature 106a in the bonding layer 108a (and/or at least one internal conductive feature, such as a BEOL feature) of the lower element 102 may be tapered or narrowed downwardly, away from the bonding surface 112a. Similarly, any bonding layers (not shown) on the backsides 116a, 116b of the elements 102, 104 may taper or narrow away from the backsides, with an opposite taper orientation relative to front side conductive features 106a, 106b of the same element.

As described above, in an anneal phase of hybrid bonding, the conductive features 106a, 106b can expand and contact one another to form a metal-to-metal direct bond. In some embodiments, the materials of the conductive features 106a, 106b of opposite elements 102, 104 can interdiffuse during the annealing process. In some embodiments, metal grains grow into each other across the bond interface 118. In some embodiments, the metal is or includes copper, which can have grains oriented along the 111 crystal plane for improved copper diffusion across the bond interface 118. In some embodiments, the conductive features 106a and 106b may include nanotwinned copper grain structure, which can aid in merging the conductive features during anneal. There is substantially no gap between the non-conductive bonding layers 108a and 108b at or near the bonded conductive features 106a and 106b. In some embodiments, a barrier layer may be provided under and/or laterally surrounding the conductive features 106a and 106b (e.g., which may include copper). In other embodiments, however, there may be no barrier layer under the conductive features 106a and 106b.

As noted in the Background above, bonding defects can occur while stacking multiple bonded structures, which can render an entire stacked bonded structure non-functional. During bonding, bonding defects can arise when bonding semiconductor elements, such as semiconductor wafers or integrated device dies. Bonding defects, such as bond voids, can result in discontinuities at the interface between said bonded semiconductor elements that cause loss of electrical coupling between bonded layers. These bond voids can form due to surface contamination, insufficient bonding pressure, non-uniform wafer planarization, and/or intrinsic material properties. Bond voids can impair device functionality by increasing electrical resistance, introducing signal integrity issues, and/or reducing mechanical stability of the bonded interface. In multi-die stacked structures, a single defective die at any level within the stack can result in a non-functional structure, leading to high yield losses. The presence of bonding defects increases manufacturing costs and delays implementations of hybrid bonding technology. The inability to maximize production and mitigate bond voids during fabrication impacts device performance and long-term reliability. Accordingly, there is a continued need for improving the formation of bonded structures and addressing bonding defects.

One solution to mitigate the impact of bond voids can include the implementation of inspection and detection techniques to identify voids at the bonding interface along with removal and replacement techniques. Inspection methods can be employed to detect bond voids at various stages of the bonding process. Once defective semiconductor elements are identified, selective removal and replacement techniques can be utilized to remove defective dies before subsequent higher temperature annealing of the substrate and bonded dies. For hybrid bonding, inspection and debonding can be performed before an anneal step that joins conductive features. After debonding, the bonding site can be reworked to restore the bond site surface integrity. A new semiconductor element can then be bonded to the cleaned or reworked bonding site, or the removed semiconductor element can undergo recovery procedures to clean the removed die or dies and prepare the bonding surface to enable rebonding to the surface of a suitable substrate if it meets quality standards. The suitable substrate can comprise the surface of a dielectric element or the backside of a bonded die, for example.

FIG. 2 illustrates a bonded structure 200 that includes multiple different types of stacks to illustrate how defects can cause the loss of an entire stack. The bonded structure 200 can include one or more stacks 202 (e.g., stacks 202a-202d) of bonded semiconductor elements 204 (e.g., dies, dummy dies, microelectronic element, singulated elements, etc.) disposed on a substrate 206. During the bonding process of the stacks 202, defects 218 (e.g., bonding defects such as bond voids, misalignment, etc.) can form at the bonding interfaces. For example, the defects 218 can be bond voids, which can be critical defects in bonded (e.g., hybrid bonded) large area semiconductor elements and stacked semiconductor elements (e.g., stack 202a). As mentioned above, stacks with a single defective semiconductor element (e.g., first semiconductor element 204a of stack 202a) can cause a non-functional stack, leading to costly yield loss and delay adoption of bonding technology. The expectation of a given incidence of defects can hinder optimal layout, increase routing complexity, and degrade electrical and thermal performance. Removing or mitigating such defective elements enhances efficiency, reliability, and overall semiconductor device quality.

As shown in FIG. 2, stack 202a can include one or more defects 218 formed between a first semiconductor element 204a and the substrate 206 at a bonding interface 212. The defect 218 can be misalignment or a bond void formed at a bonding interface 212, and can be large enough of a void or misalignment issue as to be likely to interfere with functionality (e.g., likely to prevent one or more conductive features from bonding across the bond interface). Subsequently, a plurality of semiconductor element 204b (e.g., dummy dies) can be bonded to the defective first semiconductor element 204a to match a height of the other stacks 202 of the bonded structure 200, such as stack 202c which does not contain any defects 218.

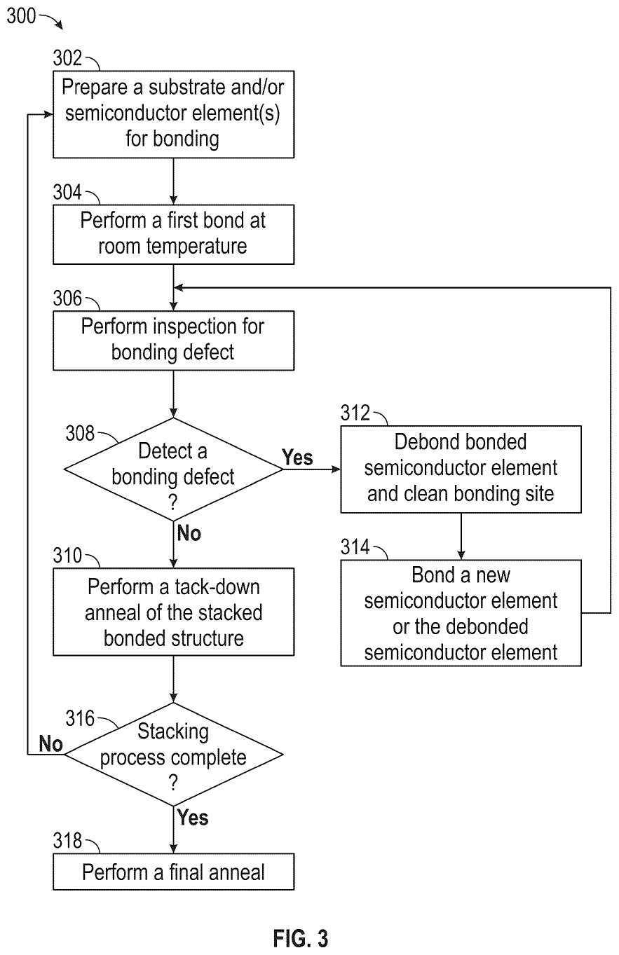

In another example, stacks 202b and 202d can include a defect 218 between a second semiconductor element 204c and a third semiconductor element 204d, rendering the third semiconductor element 204d, and possibly subsequent semiconductor elements, nonfunctional. If a defective semiconductor element is detected, one option is to continue bonding good dies to the die stack, wasting additional good dies, as illustrated for the second stack 202b, which can be costly. A second option, similar to stack 202a, is to continue the bonding stack, but with dummy or defective semiconductor elements, as illustrated for the fourth stack 202d to avoid wasting more good dies. The second option is illustrated as bonding a second plurality of dummy dies 204e to the third semiconductor element 204d of the stack stack 202d to match the heights of the other stacks 202. A third option is to not bond any additional semiconductor elements to the stack 202, which may not be possible due to molding requirements of the bonded structure 200. Lastly, a fourth option, as described below with respect to FIGS. 3-40, comprises debonding the defective semiconductor and reworking a defective bonding site, which can be paired with the recovery of the removed semiconductor element. Thus, there continues to be a need for bonding repair methods and systems.

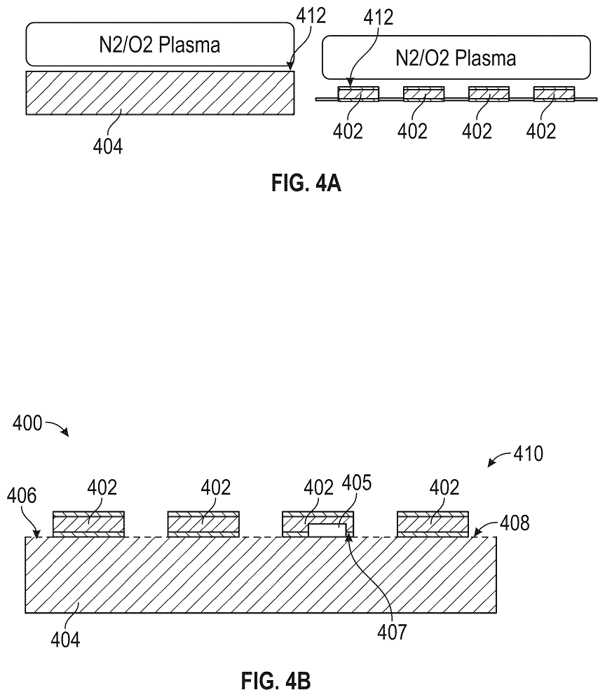

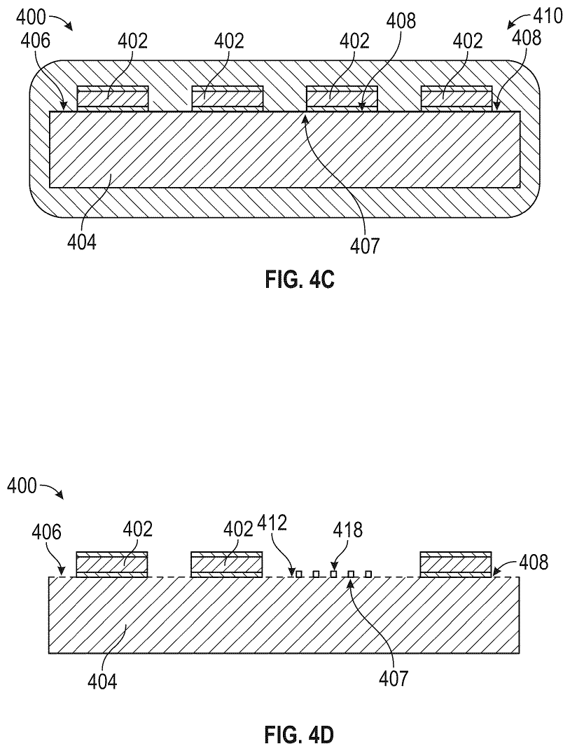

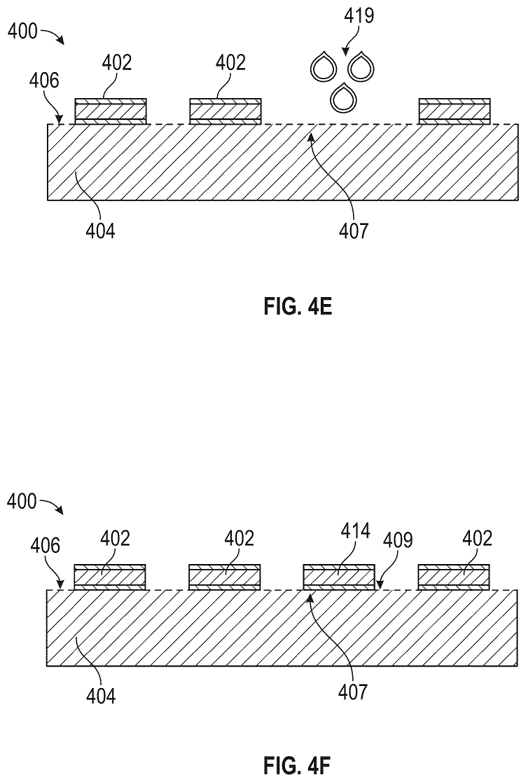

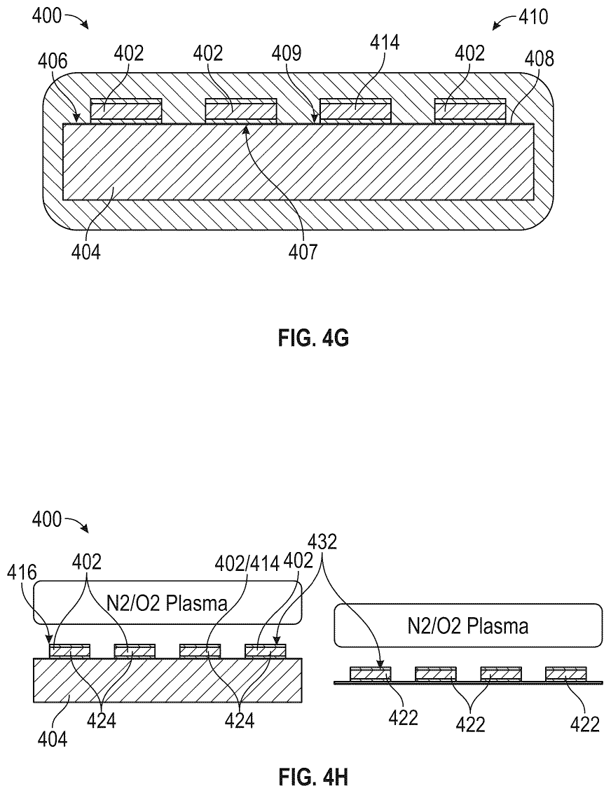

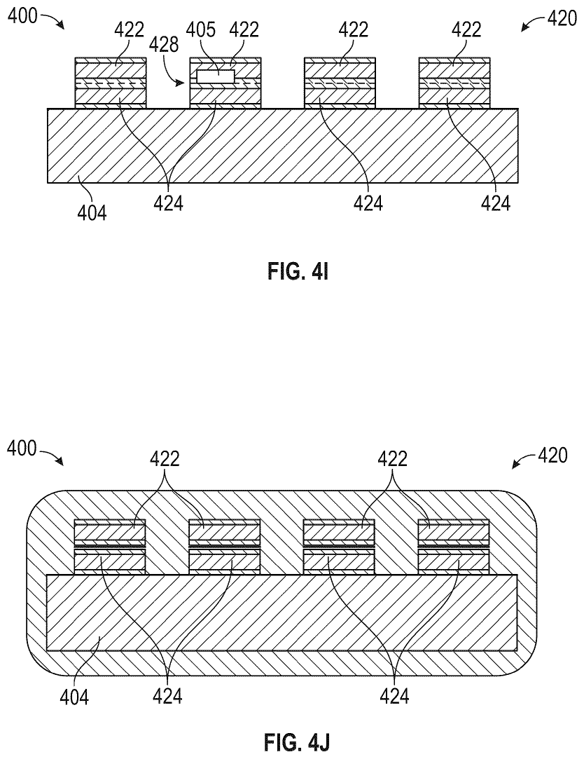

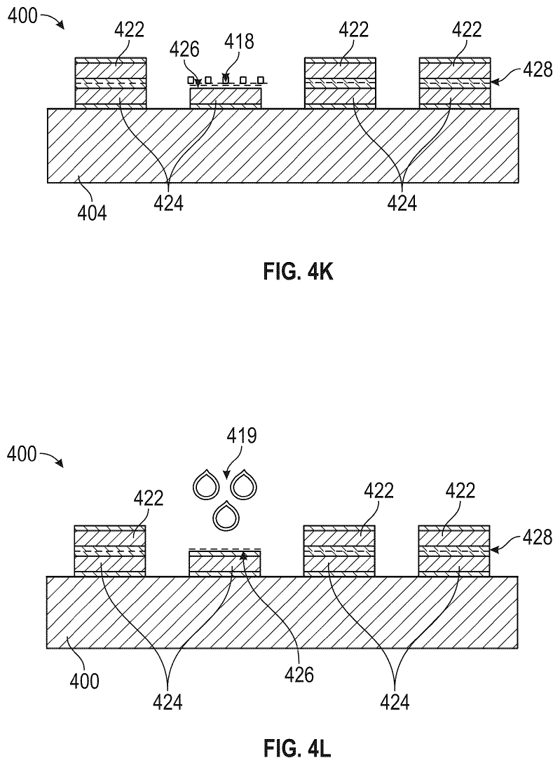

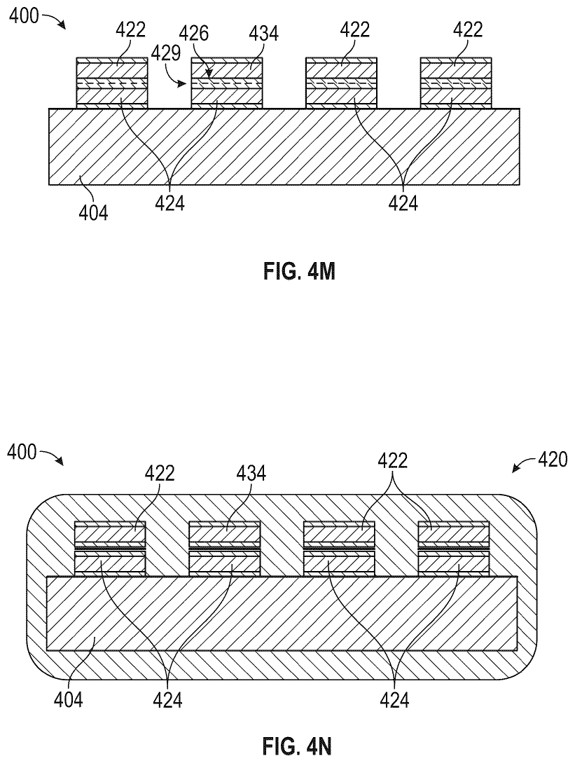

FIG. 3 illustrates an example process 300 for repairing and/or forming a bonded structure that includes inspecting the bonded structure for potential bonding defects as well as performing multiple anneals. FIGS. 4A-40 illustrate schematic side views of an example bonded structure 400 at various blocks of the process 300 shown in FIG. 3, according to various implementations herein.

As shown in FIG. 4A, at block 302, a substrate 404 and one or more microelectronic elements or dies, such as the illustrated semiconductor elements 402, are prepared for bonding. Because each of these semiconductor elements 402 can be the first die in a stack, they are also referred to herein as first semiconductor elements 402. While four first semiconductor elements 402 are shown, the skilled artisan will appreciate that the principles and advantages taught herein are applicable to forming a single stack, and multiple stacks need not be formed in parallel as shown. One or both of the substrate 404 and first semiconductor elements 402 can be prepared for bonding (e.g., direct bonding, particularly hybrid bonding). Preparing the substrate 404 and the first semiconductor elements 402 for bonding can comprise polishing a bonding surface 412 to a high degree of smoothness, as described above. As also described above, preparing the bonding surface 412 can also comprise activating the bonding surface 412. In some implementations, activating the bonding surface 412 comprises plasma activating the bonding surface 412 by exposing the bonding surface 412 to one or more plasmas, such as a nitrogen plasma and/or an oxygen plasma, or by slight etching. In some implementations, the activation or a separate process can result in terminating species, such as nitrogen, on the bonding surface 412 that can increase bonding strength. In some implementations, activating the bonding surface 412 comprises chemically activating the bonding surface 412. In some implementations, preparing the bonding surface 412 for bonding comprises rinsing the bonding surface 412 to remove any particulate matter on the bonding surface 412, and then drying the bonding surface 412. Activation can sometimes be omitted, particularly if the other surface to be bonded to the bonding surface 412 is activated. Termination can also be provided separately from or without plasma activation, such as, for example, dipping or spraying in dilute tetramethylammonium hydroxide on the bonding surface and drying the bonding surface. The drying operation for example can comprise spin drying the substrate at speeds higher than 100 rpm, higher than 1000 rpm, and or between about 1500 rpm and 5000 rpm.

As shown in FIG. 4B, at block 304, the first semiconductor element 402 can be bonded (e.g., directly bonded) to a host surface 406 of the substrate 404 at a bonding interface 408 to form an initial bonded structure 410 (e.g., an intermediate or initial stack). The first semiconductor element 402 can be bonded to the host surface 406 at a particular bonding site 407. The first semiconductor element 402 can be bonded to the substrate 404 without an intervening adhesive. The first semiconductor element 402 can be bonded to the substrate 404 at room temperature such that a first bond is formed along a bonding interface 408 (shown as a dashed line). The initial bond temperature (e.g., the first bond at room temperature) can be lower than a tack-down anneal temperature (discussed further below), and both are lower than the final anneal temperature. The first bond can be relatively weak compared to post-anneal direct bonds, but nevertheless include covalent bonding and is stronger than, for example, hydrogen bonding. The first bond at the bonding interface 408 can have a bonding energy less than about 500 mJ/m², less than about 300 mJ/m² or less than about 200 mJ/m², such as between about 50 mJ/m² and 400 mJ/m² or between about 100 mJ/m² and 200 mJ/m². The first bond can form between non-conductive surfaces of the first semiconductor element 402 and the host surface 406 of the substrate 404. The bonding energy of the first bond (as-bonded) can be lower than that of a tack-down anneal, which, in turn, is lower than the bonding energy of a final anneal. However, in some implementations the tack-down temperature can also serve as the final anneal temperature. For example the tack-down time at the tack-down temperature (e.g., a temperature of 150° C.) can be less than 30 minutes, while the final anneal times at the same tack-down temperature can range between 2 to 72 hours.

The first semiconductor elements 402 and the substrate 404 can have conductive features, such as bonding pads, vias, or lines at their bonding surfaces 412, and these conductive features can be aligned. However, at room temperature these conductive features do not form metal bonds with one another, and to the extent they are recessed, they will remain recessed relative to the non-conductive surfaces at this stage. Room temperature bonding can be conducted without application of external pressure.

At block 306, an inspection of the bonding interface 408 at the bonding site 407 along the host surface 406 between the first semiconductor elements 402 and the substrate 404 can be performed to detect any potential bonding defects, such as bond voids, misalignment, cracks, delamination, or other structural irregularities that could impact the performance, reliability, or yield of the semiconductor device. Any of the foregoing defects can be detected through optical or non-optical inspection. Bond voids, for example, refer to unbonded regions within the bonding interface that can result from surface roughness, particulate contamination, variations in material properties, and/or improper propagation of the bonding wave front. These voids can degrade the mechanical strength, the expected electrical yield of the bonded structure 400, and/or conductivity of the bonded structure 400, potentially leading to device failure over time. Misalignment can occur due to inaccurate positioning of the first semiconductor elements 402 relative to the substrate 404 or due to movement of the elements 402 after/during placement and before bonding takes place (e.g., due to an air cushion). Additionally, crack formation within the bonding interface 408 can arise due to mechanical stress, thermal cycling, or differences in coefficient of thermal expansion (CTE) between the first semiconductor elements 402 and substrate 404. These cracks can propagate over time, further compromising the integrity of the bonded structure 400. Other defects, such as delamination, can occur if there is weak adhesion between the bonded layers, leading to separation of the interface under operational conditions. Any of these types of defects, when coinciding with the position of conductive features to be bonded, can cause electrical performance issues, such as improper interconnect formation or increased resistance in circuit pathways at a later stage of the process when the conductive features are bonded.

To ensure an adequate bond, various inspection techniques can be employed. Optical inspection methods, such as infrared (IR) or visible light microscopy, can be used to detect surface defects or voids within transparent or semi-transparent bonding materials. Ultrasonic methods, such as scanning acoustic microscopy (SAM), can provide high-resolution images of subsurface defects by analyzing the reflection and transmission of ultrasonic waves at material interfaces. Laser scatterometry utilizes laser-based techniques to detect variations in the bonding interface 408 by analyzing the scattering pattern of the laser light. Additional methods, such as X-ray imaging or thermal imaging, may also be employed depending on the material properties and the nature of the defects being investigated.

At block 308, a determination is made as to whether a bonding defect was found during the inspection of block 306. If no defects are detected that satisfy a preset threshold (e.g., are critical, are above a threshold, etc.), the process 300 continues to block 310. The threshold can relate, for example, to a size of voids or other defects detected, or a degree of misalignment. As an example, the threshold for a critical defect could be about half of a minimum lateral dimension for conductive features at the bonding surface, or about a quarter of the pitch of regularly spaced conductive features at the bonding surface. Alternatively or additionally, a critical defect could depend upon the location of the void, such as overlapping or coinciding with conductive features at the bonding surface. Defects in bonding (e.g., direct bonding, particularly hybrid bonding) can be considered critical when they exceed a threshold (e.g., an acceptable threshold) and compromise the mechanical integrity, electrical performance, or long-term reliability of the bonded structure (e.g., bonded structure 400). Such defects can lead to reduced device performance, yield loss in manufacturing, and reliability issues in operational environments. For example, critical voids and local delamination can weaken adhesion, leading to mechanical failure under stress or thermal cycling. Particle contamination and misalignment can disrupt electrical connections, causing increased resistance, signal loss, or complete circuit failure. Incomplete bonding can result in weak interconnects, making the bonded structure 400 more susceptible to failure over time. At block 310, the initial bonded structure 410 can be annealed (e.g., by a tack-down anneal), as shown in FIG. 4C, at a higher temperature relative to the bonding of block 304. The tack-down anneal of block 310 can form a stronger bond energy at the bonding interface 408 (shown as a bold line in contrast to the dashed line for the relatively weaker bond in FIG. 4B) between the first semiconductor element 402 and the substrate 404. For example, the bond formed during the tack-down anneal, which can depend on the type of activation (e.g., one-side or two-side activation) and the tack-down anneal temperature, can have a bonding energy greater than the room temperature bonds of FIG. 4B, and can be, for example, between about 450 mJ/m² and 2,000mJ/m², between about 500 mJ/m²and 950 mJ/m², between about 525 mJ/m² and 750 mJ/m², or between about 550 mJ/m² and 650 mJ/m². The tack-down anneal of block 308 can comprise annealing the initial bonded structure 410 such that stronger dielectric bonds are formed between the first semiconductor element 402 and the host surface 406 substrate 404 at the bonding interface 408.

The tack-down anneal comprises a lower temperature anneal than a final temperature anneal (see block 318 and attendant description), and can be at a lower temperature, a shorter duration, or both. For example, the temperature can be selected to be less than the temperature and/or duration that would cause inelastic protrusion of any conductive features on the surface of the first semiconductor element 402 opposite to the bonded surface, and can generally also avoid inelastic expansion of conductive features on the bonded surface. Thus, any conductive features at the bond interface 408 remain unbonded after the tack-down anneal. Suitable temperatures can depend on the metallurgy of any conductive features of the first semiconductor element 402. For example, if the conductive features are comprised of copper, the tack-down anneal can occur at temperatures less than about 200° C., less than about 175° C., less than about 150° C., less than about 100° C., or less than or equal to about 80° C. If the conductive features are comprised of a nickel-tin alloy, the tack-down anneal can occur at lower temperatures than for copper, all other things being equal, such as less than about 150° C., less than less than 125° C., less than about 100° C., less than about 75° C., less than about 50° C., or less than or equal to about 40° C. At the same time, in order to adequately strengthen the dielectric bonds, the tack-down anneal can be conducted at greater than about 40° C., such as greater than about 60° C., or greater than about 70° C. Suitable tack-down anneal temperatures can be in the range of about 50-200° C., about 60-150° C., or about 70-100° C. The anneal can be conducted, for between about 1 minutes and 60 minutes, for example, for between about 5 minute and 45 minutes, or for between about 15 minutes and 30 minutes. In practice, the higher the tack down temperature the shorter the annealing times and vice versa. The tack down temperature and ambient is selected to inhibit oxidation of the conductive features on the bonding surface 412 of the substrate 404 or the backside of the bonded dies such that metal bonding remains viable.

Thus, the tack-down anneal is performed at controlled temperatures to strengthen bonding between the first semiconductor elements 402 and the substrate 404 without causing inelastic protrusion of conductive features, such as contact pads. The tack-down anneal can be performed at temperatures such that the conductive features on one or both sides of the first semiconductor element 402 do not expand beyond a non-conductive bonding layer (e.g., a dielectric layer) of the first semiconductor element 402. The conductive features can be disposed below a bonding surface of the non-conductive layer in corresponding recesses as described with respect to FIG. 1A. In some implementations, the anneal temperature is insufficient to cause the conductive features between the first semiconductor element 402 and substrate 404 to merge and bond.

Returning to block 308, if a defect, such as the void 405 shown in FIG. 4B, is detected at the bonding interface 408 during the inspection at block 306, the process 300 continues to block 312.

As shown in FIG. 4D, at block 312, a defective first semiconductor element 402 can be debonded from the host surface 406. After removal of the defective first semiconductor element 402, any remaining debris 418 (e.g., particles, impurities, etc.) at the host surface 406 along the bonding surface 412 can be removed and the host surface 406 can be prepared again for bonding. The defective first semiconductor element 402 and/or any semiconductor element bonded to the host surface 406 can be debonded via one or more, and/or a combination, of debonding techniques. An example debonding method can include delivering a fluid through nozzles to the bonding interface (e.g., bonding interface 408), which can be dispensed from a vacuum support tool equipped with protrusions surrounding the edges of the semiconductor element (e.g., the defective first semiconductor elements 402), with the nozzles embedded within these protrusions. Another example can utilize the use of thermal shock, where a temperature adjustment pad on the vacuum support tool contacts the top surface of the semiconductor element (e.g., the defective first semiconductor element 402), applying a temperature change (e.g., a sudden temperature change) to weaken or break the bond. Additionally, debonding can be performed by applying a shear force using protrusions extending from a vacuum support tool that surround the edges of the semiconductor element (e.g., the defective first semiconductor element 402). Etching can also assist with debonding, where material is removed from the edge of the semiconductor element (e.g., the defective first semiconductor element 402) or a portion of the bonding dielectric layer of the carrier (e.g., substrate 404), forming either a sloped or straight profile to facilitate separation. Furthermore, the defective first semiconductor element 402 can be debonded utilizing any debonding methods and/or techniques, and/or a combination of said techniques, similar or identical to and/or incorporate any of the features described and/or illustrated with respect to any of the devices, assemblies, methods, and/or systems described and/or illustrated in U.S. patent application Ser. No. 18/389,614, filed on Dec. 19, 2023, and titled “DEBONDING REPAIR DEVICES,” the entire disclosure of which is hereby made part of this specification as if set forth fully herein and incorporated by reference for all purposes, for all that it contains.

As shown in FIG. 4E, a cleaning fluid 419 can be applied to the host surface 406 at the bonding site 407 from which the defective first semiconductor element 402 was removed. The cleaning fluid can be a very dilute organic or inorganic acid or may be one or more organic alkaline compounds. For example, cleaning the particular bonding site 407 on the host surface 406 to remove debris 418 can include using a reagent containing at least one agent selected from an alkaline developer (e.g., an alkaline solution), hydrogen peroxide, tetra methyl ammonium hydroxide, and inorganic and organic acid, among others. A concentration or a pH of the reagent is selected to dissolve or remove debris without degrading the host surface 406. The particular bonding site 407 can also be vacuumed cleaned to further remove any remaining debris 418. For example, a vacuum pencil can be used at the particular bonding site 407 to evacuate the cleaning fluid and contaminants. The cleaning operation can further comprise of rinsing the site with droplet or vapors of deionized water (DI) or suitable alcohol and vacuuming the rinsed site to remove the rinsing solution.

Additionally, the debonded defective first semiconductor element 402 can undergo a rehabilitation process to restore its structural and surface integrity for rebonding. Rehabilitating can include a process that can include multiple steps, depending on the nature of the surface left after the debonding. Surface cleaning can be performed to remove any residual bonding materials, oxidation, and/or contamination that may have formed during the initial bonding attempt. Plasma cleaning may also be employed to improve surface activation and enhance subsequent adhesion. The debonded first semiconductor element 402 can also undergo surface conditioning techniques, such as wet-chemical cleaning or plasma treatment, to remove organic residues, native oxides, or contaminants that may inhibit effective bonding during a subsequent rebonding process. Wet-chemical treatments can effectively remove native oxides, organics, and particulate contamination while adjusting surface chemistry. Plasma treatments, including oxygen, argon, or nitrogen plasmas, can modify surface energy, enhance adhesion, or activate bonding sites. The debonded first semiconductor element 402 can also undergo surface planarization techniques, such as chemical mechanical polishing (CMP) (e.g., localized CMP), to restore the bonding surface, ensuring proper contact during a rebonding process. If any structural damage has occurred, such as microcracks or delamination, localized repair techniques can be applied, including deposition of dielectric or conductive layers via atomic layer deposition (ALD) or chemical vapor deposition (CVD). If surface roughness or damage has occurred during prior processing, these treatments may be preceded or followed by surface smoothing or etching steps to ensure compatibility with downstream integration steps. For example, if the conductive features of the defective first semiconductor element 402 have experienced oxidation or material diffusion, selective etching or re-deposition can restore their electrical properties.

Once rehabilitated, the defective first semiconductor element 402 can undergo pre-bond surface activation, such as plasma treatment or surface hydroxylation, to promote strong adhesion in the rebonding process. These measures ensure that the semiconductor element retains its functional and mechanical properties, enabling high-yield, reliable integration into the final device structure. On the other hand, yield is still improved by inspection and debonding even if the removed die is scrapped, the debonded site can be recovered for bonding another die.

As shown in FIG. 4F, at block 314, a replacement semiconductor element 414 comprising either a new semiconductor element and/or the rehabilitated first semiconductor element 402 can be bonded to the cleaned host surface 406 at the bonding site 407. The replacement semiconductor element 414 can be bonded such that a first bond (e.g., a room temperature bond) as described for block 304 is formed between the replacement semiconductor element 414 and the host surface 406. The process 300 can then return to block 306 in which the newly formed bonding interface 409 between the replacement semiconductor element 414 and the host surface 406 of the substrate 404 is inspected, e.g., optically, for defects. If no defects are detected at the bonding interface 409, the process 300 continues to block 310.

As shown in FIG. 4G, at block 310, and the initial bonded structure 410 can be subjected to a tack-down anneal as discussed with reference to FIG. 4C. As described above, the second bond formed at block 310 and in FIG. 4G can occur at a temperature greater than room temperature. The second bond can be a tack-down anneal of the bonded structure, forming dielectric bonds stronger than the first bond of block 304. After tack-down anneal, the first semiconductor elements 402 have a relatively stronger bond interface 408 (indicated by a bold line) with the substrate 404 but does not form electrical connections with the substrate 404. The process 300 can then continue to block 316.

At block 316, a determination can made as to whether additional semiconductor elements are to be stacked onto to the initial bonded structure 410. The determination can be at least based on design and functional requirements, including electrical performance, layer thickness, and/or structural integrity. If the initial bonded structure 410 is deemed to be complete, the process 300 can continue to block 318, where the bonded structure 400 undergoes a final anneal to strengthen the bond between the elements of the initial bonded structure 410. Annealing the initial bonded structure 410 can occur at a higher temperature and/or a longer duration than at block 310 both to further strengthen dielectric bonds and to form electrical connections between the first semiconductor element 402 and the host surface 406 of the substrate 404 when hybrid bonded. A final anneal temperature can be higher than the tack down anneal and sufficient to plastically deform and expand conductive features at the bond interfaces, causing inelastic protrusion, such as greater than 150° C., greater than 175° C., greater than 200° C., greater than 250° C., or greater than 300° C. Suitable temperature ranges for the final anneal are greater than the prior tack-down anneal temperature and can be between about 100° C. and 750° C., between about 150° C. and 450° C., between about 175° C. and 425° C., or between 200° C. and 400° C. The bond formed during the final anneal can have a bonding energy greater than both the room temperature bonds of FIG. 4B and the tack-down bonds of FIGS. 4C, 4G, 4J, and 4N, and can be, for example, between about 1,000 mJ/m² and 5,000mJ/m², or between about 2,000 mJ/m² and 3,000mJ/m².

If at block 316 the stacking process is not complete and more semiconductor elements are to be bonded to the initial bonded structure 410 to continue forming the bonded structure 400, the process 300 can return to block 302.

As shown in FIG. 4H, which illustrates the repeating of block 302 if additional semiconductor elements are to be bonded to the initial structure 410, one or both of a second semiconductor element 422 and an upper surface 416 of the bonded semiconductor element 424 (e.g., the first semiconductor elements 402 and/or replacement semiconductor element 414) are prepared for bonding. The upper surface 416 (e.g., backside if mounted face-down) of the bonded semiconductor element 424 and/or the second semiconductor element 422 can be prepared similarly to the first semiconductor element 402 and/or the substrate 404 of FIG. 4A.

As shown in FIG. 4I, at block 304, the second semiconductor element 422 can be bonded (e.g., directly bonded) to the upper surface 416 (a bonding site) of the bonded semiconductor element 424 at a second bonding interface 428 without an intervening adhesive to form a stack or an extended bonded structure 420. The bond between the second semiconductor element 422 and bonded semiconductor element 424 can be a first bond as described above with respect to block 304 and FIG. 4B, which can be relatively weak. As previously described, the first bond can form between non-conductive surfaces of the second semiconductor element 422 and the bonded semiconductor element 424. The second semiconductor element 422 and the bonded semiconductor element 424 can have conductive features, such as bonding pads, at their bonding surfaces 432, and these conductive features can be aligned. However, at room temperature these conductive features do not form metal bonds with one another, and to the extent they are recessed, they will remain recessed relative to the non-conductive surfaces at this stage.

At block 306, an inspection of the second bonding interface 428 between the second semiconductor element 422 and the bonded semiconductor element 424 can be performed for detecting any bonding defects. As described above, the bonding defect can comprise a bond voids, misalignment between respective elements, crack formation, etc. The inspection can be performed via an optical inspection, ultrasonic methods, laser scatterometry, and the like.

At block 308, a determination is made as to whether a bonding defect was found during the inspection of block 306. If no bonding defects are detected (e.g., critical, above a threshold, etc.), the process 300 continues to block 310. At block 310, the extended bonded structure 420 can be annealed (e.g., a tack-down anneal), as described above with respect to block 310 and FIG. 4C. The result of the tack-down anneal is shown in FIG. 4J, forming stronger dielectric bonds than the bonding of block 304. As described above, the tack-down anneal is at a lower temperature than a final anneal and does not cause inelastic expansion of any conductive features (e.g., conductive pads) of the second semiconductor element 422, such that the conductive features of the second semiconductor element 422 do not expand beyond the dielectric bonding surface of the second semiconductor element 422. Any conductive features can remain disposed below a surface of the dielectric bonding surface in corresponding recesses.

Returning to block 308, if a bonding defect is detected at a second bonding interface 428 during the inspection at block 306, the process 300 continues to block 312. As shown in FIG. 4K, at block 312, the second semiconductor element 422 can be debonded from the bonding site 426, as described above with respect to block 312 and FIG. 4D. As also described above with respect to FIG. 4D, after removal of the second semiconductor element 422, any remaining debris 418 (e.g., particles, impurities, etc.) at the bonding site 426 on the upper surface 416 can be removed and the bonding site 426 can be prepared again for bonding. As shown in FIG. 4L, the cleaning fluid 419 can be applied to the bonding site 426 to remove debris without degrading the bonding site 426, as described above with respect to FIG. 4E. Additionally, the debonded second semiconductor element 422 can be rehabilitated for rebonding as discussed with respect to FIG. 4E.

As shown in FIG. 4M, at block 314, a replacement semiconductor element 434 comprising either a new semiconductor element and/or the rehabilitated second semiconductor element 422 can be bonded to the cleaned bonding site 426. The replacement semiconductor element 434 can be bonded such that a first bond (e.g., a room temperature bond) as described for block 304 is formed between the replacement semiconductor element 434 and the bonding site 426. The process can return to block 306 in which the newly formed bonding interface 429 between the replacement semiconductor element 434 and the bonding site 426 is inspected for bonding defects. If no bonding defects are detected at the bonding interface 429, the process 300 continues to block 310 and the extended bonded structure 420 can be annealed using a tack-down anneal, as shown in FIG. 4N, to form the bonded structure 400, and the process 300 continues to block 316. As described above with respect to block 310 and FIG. 4C, the tack-down anneal can occur at a temperature greater than room temperature but below the temperature of a final anneal, forming a stronger dielectric bond than the first bond of block 304 but avoiding protrusion of any upper surface (e.g., backside) conductive features or merger of the conductive features at the interface between the stacked dies 424, 422 or 434.

The process 300 can be repeated until a desired number of microelectronic elements are bonded to the bonded structure and the condition of block 316 is satisfied. For example, as shown in FIG. 4O, if more microelectronic elements are to be bonded to the bonded structure 400, the process 300 can return to block 302 and a new semiconductor element 442 (e.g., an additional semiconductor element) and an upper surface 436 of the bonded semiconductor element 444 (e.g., the second semiconductor element 422 and/or replacement semiconductor element 434) are prepared for bonding.

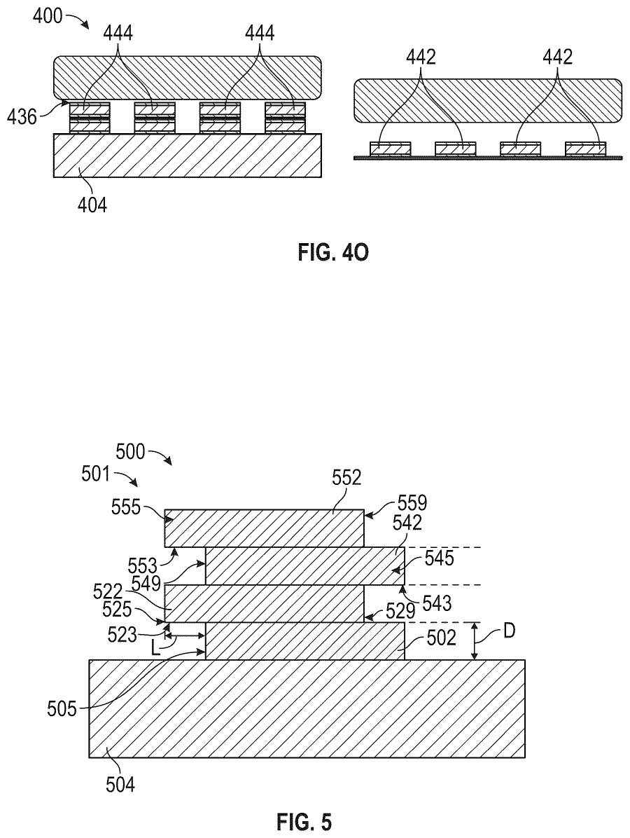

FIG. 5 illustrates an example bonded stack 500, according to various implementations. Unless otherwise noted, components of FIG. 5 can be the same as or generally similar to like-numbered components of FIGS. 4A-4O. As shown in FIG. 5, the bonded stack 500 can include a plurality of microelectronic elements 501 (e.g., 2, 3, 4, 5, etc.) disposed over a substrate 504. For example, a first semiconductor element 502 can be attached (e.g., flip chip bonded, directly bonded, particularly hybrid bonded) to the substrate 504, a second semiconductor element 522 can be bonded (e.g., directly bonded, particularly hybrid bonded) to the first semiconductor element 502. The plurality of microelectronic elements 501 can have a die thickness D at least between about 5 μm and 300 μm, between about 30 μm and 250 μm, or between about 50 μm and 200 μm. As non-limiting examples, the plurality of microelectronic elements 501 can have a thickness D of about 50 μm or about 200 μm. The microelectronic elements 501 can be staggered from one another such that an overlying microelectronic element extends beyond an edge of the underlying microelectronic element. For example, the second semiconductor element 522 can be aligned over the first semiconductor element 502 such that a portion 525 of the second semiconductor element 522 extends beyond an edge 505 of the first semiconductor element 502. An overhang 523 can be formed by the extended portion 525 of the second semiconductor element 522. The overhang 523 can be used to pry the second semiconductor element 522 from the first semiconductor element 502. The overhang 523 can have a length L at least between about 25 μm and 500 μm, between about 40 μm and 300 μm, or between about 50 μm and 200 μm. As non-limiting examples, the overhang 523 can have a length L of about 200 μm or about 50 μm. In the illustrated example, where all of the stacked microelectronic elements 501 have the same dimensions, an edge 529 of the second semiconductor element 522 opposite the overhang 523 is inset from the underlying first semiconductor element 502 by the same amount as the overhang length L.

The overhang 523 can be greater than a largest pad width of the plurality of microelectronic elements 501, where the pad width refers to the dimension of the die pad that functions as the contact region for electrical, thermal, or mechanical interfacing. The overhang 523 can be formed through off-center dicing within dicing streets, wherein the cutting path is displaced from the center of the dicing street by the amount of the desired overhang, such that the staggered arrangement can be prepared without the need to adjust photolithography masks. This can modify the material distribution at the periphery of the plurality of microelectronic elements 501. In some arrangements, the width of the dicing street could be expanded to facilitate larger dimensions of the overhang 523. For example, the dicing street could be double or triple standard widths (currently about 80 μm), allowing for greater options for where to dice and how large the overhang 523 can be. Having a larger overhang 523 can assist with debonding the first semiconductor element 502.

As shown in FIG. 5, a third semiconductor element 542 can be directly bonded, and particularly hybrid bonded, to the second semiconductor element 522. The third semiconductor element 542 can be offset from the second semiconductor element 522 such that a portion 545 of the third semiconductor element 542 extends beyond the edge 529 of the second semiconductor element 522, forming a second overhang 543. The second overhang 543 of the third semiconductor element 542 can extend at least partially over the first semiconductor element 502 and is on the opposite side from the first overhang 523. An edge 549 of the third semiconductor element 522 opposite the second overhang 543 is inset from the underlying second semiconductor element 522 by the same amount as the overhang length L. The die pads or TSVs of the third semiconductor element 542 align with the die pads or TSVs of the second semiconductor element 522. Additionally, a fourth semiconductor element 552 can be directly bonded, and particularly hybrid bonded, to the third semiconductor element 542. The fourth semiconductor element 552 can be offset from the third semiconductor element 542 such that a portion 555 of the fourth semiconductor element 552 extends beyond the edge 549 of the third semiconductor element 542, forming a third overhang 553. The third overhang 553 of the fourth semiconductor element 552 extends at least partially over the second semiconductor element 522 and is on the opposite side from the second overhang 543. An edge 559 of the fourth semiconductor element 552 opposite the third overhang 553 is inset from the underlying third semiconductor element 542 by the same amount as the overhang length L. The die pads or TSVs of the fourth semiconductor element 552 can align with the die pads or TSVs of the third semiconductor element 542.

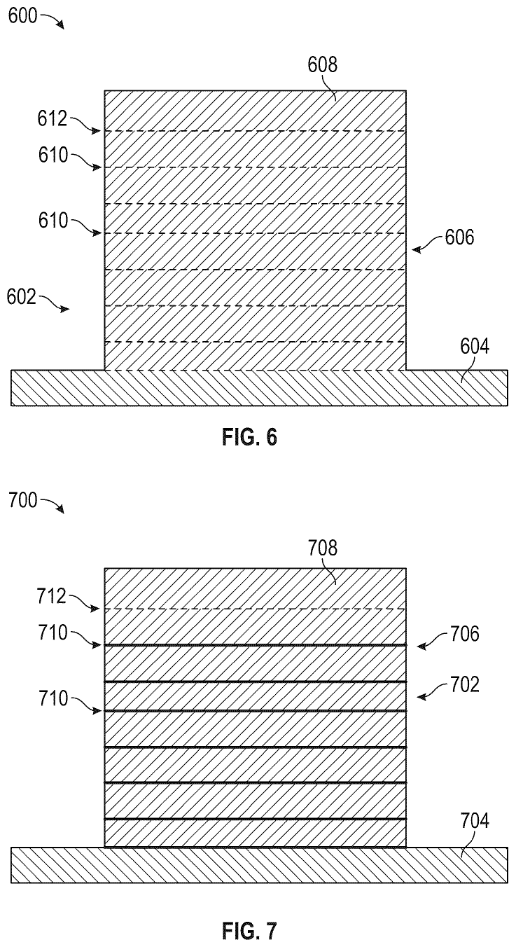

FIG. 6 illustrates an intermediate bonded structure 600 prior to final anneal that does not employ the intermediate or tack-down anneal described herein. FIG. 7 illustrates an intermediate bonded structure 700 prior to final anneal, completed by process 300 described herein, including tack-down anneals between bonding processes.

As shown in FIG. 6, the intermediate bonded structure 600 can comprises a stack of microelectronic elements 602 disposed over a substrate 604. The stack of microelectronic elements 602 can comprise a plurality of intermediate microelectronic elements 606 and a final microelectronic element 608. Each of the intermediate microelectronic elements 606 can be bonded to an adjacent intermediate microelectronic elements 606 at a bonding interface 610 (shown as a dashed line). Each of the bonding interfaces 610 can comprise a same or similar bond strength relative to the other bonding interfaces 610. Additionally, the final microelectronic element 608 of the stack of semiconductor elements 602 can include a bonding interface 612 (also shown as a dashed line) which comprises a same or similar bond strength as the bonding interfaces 610 between the intermediate microelectronic elements 606. In this process, the bonding interfaces 610 are all formed by room temperature bonding without any annealing, and accordingly all of the interfaces 610, 612 have relatively weak bond energy (e.g., less than about 200 mJ/m²) and no electrical connections are formed at this intermediate stage. Annealing to accomplish both strengthening dielectric bonding and to accomplish metal bonding is left to the end of the stacking process to avoid the lower dies to multiple anneals.

As shown in FIG. 7, an intermediate bonded structure 700 can comprise a substrate 704 and a stack of microelectronic elements or dies, such as the illustrated semiconductor elements 702 disposed over the substrate 704. The stack of semiconductor elements 702 can comprise a plurality of intermediate semiconductor elements 706 and a final semiconductor element 708. Each of the semiconductor elements 706 can be bonded to an adjacent intermediate semiconductor element 706 at a bonding interface 710. The bond energies of the bonding interfaces 710 (shown as a bold line) can be greater than the bond energies at the bonding interfaces 610 of FIG. 6 (e.g., greater than about 600 mJ/m²) due to intervening tack-down anneals in the stacking process, but electrical connections are not complete at this intermediate stage. In some arrangements, because the lower dies are subject to more tack-down anneals while the upper dies are subject to fewer tack-down anneals, at least one bonding interface 710 between the intermediate semiconductor elements 706 can comprise a greater bond strength relative to other bonding interfaces 710 of the intermediate semiconductor elements 706. The final semiconductor element 708 of the stack of semiconductor elements 702 can be bonded to the plurality of intermediate semiconductor elements 706 along the bonding interface 712.

The bonding interface 712 (shown as a dashed line) between the final semiconductor element 708 and the plurality of intermediate semiconductor elements 706 can comprise a lower bond strength energy (e.g., less than about 200 mJ/m²) relative to the bonding interfaces 710 of the intermediate semiconductor elements 706 because it has not been subjected to a tack-down anneal. The lower bond strength can comprise a low temperature anneal to strengthen dielectric bonds without joining recessed metal contacts between the final semiconductor element 708 and the plurality of intermediate semiconductor elements 706. The lower bond strength at the bonding interface 712 can allow the final semiconductor element 708 to be selectively removeable from the plurality of intermediate semiconductor elements 706. On the other hand, the higher bond strengths of the lower bonding interfaces 710 facilitates debonding of the uppermost die if inspection shows defects, without debonding the lower elements. In some implementations, a stack or multiple stacks of bonded semiconductor elements can be bonded to a substrate, each stack disposed relative to each other at one or more defined pitches. After inspection of the bonded structures, a bonded stack with critical defects can be debonded. The recovered site is cleaned, reactivated if necessary, and a replacement stack is bonded to the recovered site. In some implementations, the stack of semiconductor elements comprises a molded material at least encapsulating the sidewalls of the semiconductor elements. In some embodiments, a stack of bonded semiconductor elements may be stacked over another stack of semiconductor elements. In some implementations, more than one type of structure can be bonded on the substrate (404, 504, 604, 704), such as a first structure comprising a stack of bonded semiconductor elements, a second structures comprising an individual directly bonded semiconductor element, etc. A width of the second structure may be geometrically smaller or larger than a width of the first structure. In practice, after the high temperature processing of the substrate with bonded semiconductor elements to electrically connect the conductive features of the various bonded elements, the substrate can be singulated by known methods before further processing.

In some implementations, each of the substrate 704 and/or plurality of intermediate semiconductor elements 706 of the stack of semiconductor elements 702 can be offset from one another (see FIG. 5) such that an overhang is formed at each semiconductor element. The overhang can provide a location for debonding (e.g., mechanically debonding such as prying) the final semiconductor element 708 from the plurality of intermediate semiconductor elements 708.

### Additional Examples

In some aspects, a method of forming a stack of microelectronic elements can include: directly bonding a first microelectronic element to a host surface at a first bond interface to form an initial bonded structure; inspecting the first bond interface for bonding defects; initially annealing the initial bonded structure if no critical bonding defect is detected; directly bonding a second microelectronic element over the first microelectronic element after initially annealing to form a stack; and annealing the stack.

In some implementations, the method includes: debonding the first microelectronic element from the first bond interface if at least one or more bonding defects are detected; and cleaning the host surface after the first microelectronic element has been debonded, wherein cleaning the host surface includes applying an alkaline solution to and vacuuming the host surface. In some implementations, directly bonding the first microelectronic element to the host surface includes forming a bond having a bonding energy of less than 200 mJ/m². In some implementations, directly bonding the first microelectronic element to the host surface includes forming a bond having a bonding energy of less than 300 mJ/m². In some implementations, directly bonding the first microelectronic element to the host surface includes forming a bond having a bonding energy between 50 mJ/m²and 400 mJ/m². In some implementations, a temperature of annealing the stack is less than 85° C.

In some implementations, the method includes repeating a stacking of microelectronic elements until a desired number of microelectronic elements are stacked together. In some implementations, the method includes performing a final anneal to bond the stack once the desired number of microelectronic elements is achieved. In some implementations, a temperature of the final anneal is greater than 85° C. In some implementations, the final anneal comprises forming a bond having a bonding energy between 1,000 mJ/m² and 5,000 mJ/m². In some implementations, initially annealing the initial bonded structure includes forming a bond having a bonding energy of less than 600 mJ/m². In some implementations, initially annealing the initial bonded structure comprises forming a bond having a bonding energy between 500 mJ/m²and 950 mJ/m².

In some implementations, annealing the stack occurs at a higher temperature than initially annealing the initial bonded structure to form electrical connections between the first microelectronic element and the host surface or between the first microelectronic element and the second microelectronic element. In some implementations, annealing the stack includes forming dielectric bonds between the first microelectronic element and the host surface at the first bond interface without causing inelastic protrusion of conductive pads of the first microelectronic element such that the conductive pads of the first microelectronic element do not expand beyond a dielectric layer of the first microelectronic element, the conductive pads disposed below a top surface of the dielectric layer in corresponding recesses.

In some implementations, inspecting the first bond interface is performed via optical inspection. In some implementations, the bonding defects include at least one of a bond void and a misalignment between the first microelectronic element and the host surface.

In some aspects, a method of forming a stacked bonded structure can include: directly bonding a first semiconductor element to a bonding site of a substrate at a first bond interface; inspecting the first bond interface for bonding defects after bonding the first semiconductor element to the bonding site; debonding the first semiconductor element from the bonding site if at least one or more bonding defects are detected that is above a threshold severity; initially annealing the first semiconductor element and the substrate if no bonding defects above the threshold severity are detected; and directly bonding a second semiconductor element to the first semiconductor element after initially annealing.

In some implementations, the method includes cleaning the bonding site after the first semiconductor element has been debonded, wherein cleaning the bonding site includes applying an alkaline solution to and vacuuming the bonding site. In some implementations, directly bonding the first semiconductor element to the bonding site or directly bonding the second semiconductor element to the first semiconductor element includes forming a bond having a bonding energy of less than 200 mJ/m². In some implementations, directly bonding the first semiconductor element to the bonding site or directly bonding the second semiconductor element to the first semiconductor element includes forming a bond having a bonding energy of less than 300 mJ/m². In some implementations, directly bonding the first semiconductor element to the bonding site or directly bonding the second semiconductor element to the first semiconductor element includes forming a bond having a bonding energy between 50 mJ/m² and 400 mJ/m².

In some implementations, the method includes annealing the second semiconductor element and the first semiconductor element, wherein, during the annealing of the second semiconductor element and the first semiconductor element, dielectric bonds are formed between the second semiconductor element and the first semiconductor element without causing inelastic protrusion of conductive pads of the first semiconductor element, and wherein the conductive pads of the first semiconductor element do not expand beyond a dielectric layer of the first semiconductor element, the conductive pads disposed below a top surface of the dielectric layer in corresponding recesses. In some implementations, a temperature of annealing the second semiconductor element and the first semiconductor element is less than 85° C. In some implementations, annealing the second semiconductor element and the first semiconductor element occurs at a higher temperature than initially annealing the first semiconductor element and the substrate to form electrical connections between the first semiconductor element and the first semiconductor element or between the first semiconductor element and the second semiconductor element.

In some implementations, the method includes repeating a stacking of semiconductor elements until a desired number of semiconductor elements are stacked together. In some implementations, the method includes performing a final anneal to bond the stacked bonded structure once the desired number of semiconductor elements is achieved. In some implementations, a temperature of the final anneal is greater than 85° C. In some implementations, the final anneal includes forming a bond having a bonding energy between 1,000 mJ/m² and 5,000 mJ/m². In some implementations, initially annealing the first semiconductor element and the substrate includes forming a bond having a bonding energy of less than 600 mJ/m². In some implementations, initially annealing the first semiconductor element and the substrate includes forming a bond having a bonding energy between 500 mJ/m² and 950 mJ/m². In some implementations, inspecting the first bond interface is performed via optical inspection. In some implementations, the bonding defects include at least one of a bond void and a misalignment between the first semiconductor element and the bonding site.

In some aspects, a method of forming a stacked bonded structure can include: directly bonding a first semiconductor element to a bonding site of a substrate at a bond interface; debonding the first semiconductor element from the bonding site if a critical bonding defect; and directly bonding the first semiconductor element to the bonding site of the substrate after cleaning the bonding site.

In some implementations, the method includes rehabilitating the debonded first semiconductor element prior to directly bonding the first semiconductor element to the bonding site of the substrate. In some implementations, the method includes: initially annealing the first semiconductor element and the substrate if no critical bonding defect are detected; and directly bonding a second semiconductor element to the first semiconductor element after initially annealing. In some implementations, initially annealing the first semiconductor element and the substrate includes forming a bond having a bonding energy of less than 600 mJ/m². In some implementations, initially annealing the first semiconductor element and the substrate includes forming a bond having a bonding energy between 500 mJ/m² and 950 mJ/m².

In some implementations, the method includes annealing the second semiconductor element and the first semiconductor element, wherein, during the annealing of the second semiconductor element and the first semiconductor element, dielectric bonds are formed between the second semiconductor element and the first semiconductor element without causing inelastic protrusion of conductive pads of the first semiconductor element, and wherein the conductive pads of the first semiconductor element do not expand beyond a dielectric layer of the first semiconductor element, the conductive pads disposed below a top surface of the dielectric layer in corresponding recesses. In some implementations, a temperature of annealing the second semiconductor element and the first semiconductor element is less than 85° C. In some implementations, annealing the second semiconductor element and the first semiconductor element occurs at a higher temperature than initially annealing the first semiconductor element and the substrate to form electrical connections between the first semiconductor element and the first semiconductor element or between the first semiconductor element and the second semiconductor element.

In some implementations, the method includes: inspecting the bond interface for bonding defects after bonding the first semiconductor element to the bonding site; and cleaning the bonding site after the first semiconductor element has been debonded. In some implementations, wherein cleaning the bonding site includes applying an alkaline or acidic solution to the bonding site and vacuuming the bonding site to remove the applied cleaning solution and contaminants. The cleaning operation may further comprise of rinsing the site with droplet or vapors of deionized water (DI) or suitable alcohol and vacuuming the rinsed site to remove the rinsing solution.

In some implementations, the method includes initially annealing the first semiconductor element and the substrate after directly bonding the first semiconductor element to the bonding site of the substrate after cleaning the bonding site; and directly bonding a second semiconductor element to the first semiconductor element after initially annealing. In some implementations, initially annealing the first semiconductor element and the substrate includes forming a bond having a bonding energy of less than 600 mJ/m². In some implementations, initially annealing the first semiconductor element and the substrate includes forming a bond having a bonding energy between 500 mJ/m²and 950 mJ/m². In some implementations, the method includes annealing the second semiconductor element and the first semiconductor element, wherein, during the annealing of the second semiconductor element and the first semiconductor element, dielectric bonds are formed between the second semiconductor element and the first semiconductor element without causing inelastic protrusion of conductive pads of the first semiconductor element, and wherein the conductive pads of the first semiconductor element do not expand beyond a dielectric layer of the first semiconductor element, the conductive pads disposed below a top surface of the dielectric layer in corresponding recesses. In some implementations, a temperature of annealing the second semiconductor element and the first semiconductor element is less than 85° C. In some implementations, annealing the second semiconductor element and the first semiconductor element occurs at a higher temperature than initially annealing the first semiconductor element and the substrate to form electrical connections between the first semiconductor element and the first semiconductor element or between the first semiconductor element and the second semiconductor element.

In some implementations, after debonding the first semiconductor element from the bonding site if a critical bonding defect is detected, bonding a second semiconductor element to the bonding site. In some implementations, directly bonding the first semiconductor element to the bonding site includes forming a bond having a bonding energy of less than 200 mJ/m². In some implementations, directly bonding the first semiconductor element to the bonding site includes forming a bond having a bonding energy of less than 300 mJ/m². In some implementations, directly bonding the first semiconductor element to the bonding site includes forming a bond having a bonding energy between 50 mJ/m² and 400 mJ/m². In some implementations, the method includes repeating a stacking of semiconductor elements until a desired number of semiconductor elements are stacked together. In some implementations, the method includes performing a final anneal to bond the stacked bonded structure once the desired number of semiconductor elements is achieved. In some implementations, a temperature of the final anneal is greater than 85° C. In some implementations, the final anneal includes forming a bond having a bonding energy between 1,000 mJ/m² and 5,000 mJ/m².

In some implementations, inspecting the bond interface is performed via optical inspection. In some implementations, the bonding defects include at least one of a bond void and a misalignment between the first semiconductor element and the bonding site.

In some aspects, a bonded structure can include a substrate and a stack of semiconductor elements disposed on the substrate. The stack of semiconductor elements includes a plurality of intermediate semiconductor elements. Each semiconductor element of the plurality of intermediate semiconductor elements is bonded to an adjacent intermediate semiconductor element at a bonding interface, wherein at least one bonding interface among the plurality of intermediate semiconductor elements includes a greater bond strength relative to other bonding interfaces of the plurality of intermediate semiconductor elements. The bonded structure also includes a final semiconductor element bonded to the plurality of intermediate semiconductor elements. The bonding interface between the final semiconductor element and the plurality of intermediate semiconductor elements includes a lower bond strength relative to the bonding interfaces of the plurality of intermediate semiconductor elements.

In some implementations, the lower bond strength allows the final semiconductor element to be selectively removeable from the plurality of intermediate semiconductor elements. In some implementations, the stack of semiconductor elements includes dies. In some implementations, each of the stack of semiconductor elements are offset from one another such that an overhang is formed at each semiconductor element. In some implementations, the overhang provides a location for prying each semiconductor element from an underlying semiconductor element of the plurality of intermediate semiconductor elements. In some implementations, the lower bond strength includes a low temperature anneal to strengthen dielectric bonds without joining recessed metal contacts between the plurality of intermediate semiconductor elements and the final semiconductor element.

In some aspects, a method of forming a stacked bonded structure can include: bonding a second semiconductor element to a first semiconductor element at a first bond interface, wherein the second semiconductor element is offset from the first semiconductor element such that a portion of the second semiconductor element extends beyond an edge of the first semiconductor element forming an overhang; inspecting the first bond interface for bonding defects after bonding the second semiconductor element to the first semiconductor element; and debonding the second semiconductor element from the first bond interface if a critical bonding defect is detected.

In some implementations, bonding the second semiconductor element to the first semiconductor element includes forming a bond having a bonding energy of less than 200 mJ/m². In some implementations, bonding the second semiconductor element to the first semiconductor element includes forming a bond having a bonding energy of less than 300 mJ/m². In some implementations, bonding the second semiconductor element to the first semiconductor element includes forming a bond having a bonding energy between 50 mJ/m² and 400 mJ/m². In some implementations, the method includes: initially annealing the second semiconductor element and the first semiconductor element if no critical bonding defect is detected; and bonding a third semiconductor element to the second semiconductor element after initially annealing, wherein the third semiconductor element is offset from the second semiconductor element such that a portion of the third semiconductor element extends beyond an edge of the second semiconductor element forming a second overhang. In some implementations, the third semiconductor element extends at least partially over the first semiconductor element.

In some implementations, inspecting the stacked bonded structure for a bonding defect is performed via optical inspection. In some implementations, the method includes cleaning the first semiconductor element after the second semiconductor element has been debonded, wherein cleaning the first semiconductor element includes applying an alkaline solution to the first semiconductor element and vacuuming the first semiconductor element. In some implementations, the method includes bonding a third semiconductor element to the first semiconductor element, wherein the third semiconductor element includes the debonded second semiconductor element or another semiconductor element. In some implementations, the method includes initially annealing the third semiconductor element and the first semiconductor element. In some implementations, initially annealing the third semiconductor element and the first semiconductor element includes forming a bond having a bonding energy of less than 600 mJ/m². In some implementations, initially annealing the third semiconductor element and the first semiconductor element includes forming a bond having a bonding energy between 500 mJ/m² and 1,000 mJ/m².

In some implementations, the bonding defect includes at least one of a bond void and a misalignment between the second semiconductor element and the first semiconductor element. In some implementations, the overhang provides a location for prying the second semiconductor element from the first semiconductor element.

In some aspects, a stacked bonded structure can include a substrate and a stack of semiconductor elements disposed on the substrate. The stack of semiconductor elements includes a plurality of intermediate semiconductor elements and a final semiconductor element, where each semiconductor element of the stack of semiconductor elements is offset from an adjacent semiconductor element of the stack of semiconductor elements such that an overhang is formed at each semiconductor element.

In some implementations, each semiconductor element of the plurality of intermediate semiconductor elements is bonded to an adjacent semiconductor element with a first bond strength, and wherein the final semiconductor element is bonded to the plurality of intermediate semiconductor elements with a second bond strength, the second bond strength having a lower bond strength than the first bond strength. In some implementations, the second bond strength allows the final semiconductor element to be selectively removeable from the plurality of intermediate semiconductor elements. In some implementations, the second bond strength includes a low temperature anneal to strengthen dielectric bonds without joining recessed metal contacts between the plurality of intermediate semiconductor elements and the final semiconductor element. In some implementations, the stack of semiconductor elements includes dies.

In some aspects, a stacked bonded structure can include a second semiconductor element directly bonded to a first semiconductor element at a first bond interface, where the second semiconductor element is offset from the first semiconductor element such that a portion of the second semiconductor element extends beyond an edge of the first semiconductor element forming an overhang. The stacked bonded structure also includes a third semiconductor element directly bonded to the second semiconductor element, where the third semiconductor element is offset from the second semiconductor element such that a portion of the third semiconductor element extends beyond an edge of the second semiconductor element forming a second overhang.

In some implementations, the third semiconductor element extends at least partially over the first semiconductor element. In some implementations, the first semiconductor element, the second semiconductor element, and the third semiconductor element include dies. In some implementations, the first semiconductor element is disposed on a substrate.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number, respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. For example, while illustrated embodiments include preparation for direct hybrid bonding, the skilled artisan will appreciate that the techniques taught herein can be useful for direct metal bonding even in the absence of direct dielectric bonding. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. It is also contemplated that various combinations or sub-combinations of the specific features and aspects of the embodiments may be made and still fall within the scope. The accompanying claims and their equivalents are intended to cover such forms or modifications as would fall within the scope and spirit of the disclosure.

1-87. (canceled)

88. A method of forming a stack of microelectronic elements, the method comprising:
directly bonding a first microelectronic element to a host surface at a first bond interface to form an initial bonded structure;
inspecting the first bond interface for bonding defects;
initially annealing the initial bonded structure if no critical bonding defect is detected;
directly bonding a second microelectronic element over the first microelectronic element after initially annealing to form a stack; and
annealing the stack.

89. The method of claim 88, further comprising:
debonding the first microelectronic element from the first bond interface if at least one or more bonding defects are detected; and
cleaning the host surface after the first microelectronic element has been debonded, wherein cleaning the host surface comprises applying an alkaline solution to and vacuuming the host surface.

90. The method of claim 88, wherein directly bonding the first microelectronic element to the host surface comprises forming a bond having a bonding energy between 50 mJ/m² and 400 mJ/m².

91. The method of claim 88, further comprising repeating a stacking of microelectronic elements until a desired number of microelectronic elements are stacked together and performing a final anneal to bond the stack once the desired number of microelectronic elements is achieved.

92. The method of claim 91, wherein the final anneal comprises forming a bond having a bonding energy between 1,000 mJ/m² and 5,000 mJ/m².

93. The method of claim 88, wherein initially annealing the initial bonded structure comprises forming a bond having a bonding energy between 500 mJ/m² and 950 mJ/m².

94. The method of claim 88, wherein annealing the stack occurs at a higher temperature than initially annealing the initial bonded structure to form electrical connections between the first microelectronic element and the host surface or between the first microelectronic element and the second microelectronic element.

95. The method of claim 88, wherein annealing the stack comprises forming dielectric bonds between the first microelectronic element and the host surface at the first bond interface without causing inelastic protrusion of conductive pads of the first microelectronic element such that the conductive pads of the first microelectronic element do not expand beyond a dielectric layer of the first microelectronic element, the conductive pads disposed below a top surface of the dielectric layer in corresponding recesses.

96. A method of forming a stacked bonded structure, the method comprising:
directly bonding a first semiconductor element to a bonding site of a substrate at a first bond interface;
inspecting the first bond interface for bonding defects after bonding the first semiconductor element to the bonding site;
debonding the first semiconductor element from the bonding site if at least one or more bonding defects are detected that is above a threshold severity;
initially annealing the first semiconductor element and the substrate if no bonding defects above the threshold severity are detected; and
directly bonding a second semiconductor element to the first semiconductor element after initially annealing.

97. The method of claim 96, further comprising cleaning the bonding site after the first semiconductor element has been debonded, wherein cleaning the bonding site comprises applying an alkaline solution to and vacuuming the bonding site.

98. The method of claim 96, further comprising annealing the second semiconductor element and the first semiconductor element, wherein, during the annealing of the second semiconductor element and the first semiconductor element, dielectric bonds are formed between the second semiconductor element and the first semiconductor element without causing inelastic protrusion of conductive pads of the first semiconductor element, and wherein the conductive pads of the first semiconductor element do not expand beyond a dielectric layer of the first semiconductor element, the conductive pads disposed below a top surface of the dielectric layer in corresponding recesses.

99. The method of claim 96, further comprising repeating a stacking of semiconductor elements until a desired number of semiconductor elements are stacked together and performing a final anneal to bond the stacked bonded structure once the desired number of semiconductor elements is achieved.

100. A method of forming a stacked bonded structure, the method comprising:
directly bonding a first semiconductor element to a bonding site of a substrate at a bond interface;
detecting a bonding defect at the bond interface;
debonding the first semiconductor element from the bonding site after detecting the bonding defect; and
again directly bonding the first semiconductor element to the bonding site or another bonding site after debonding.

101. The method of claim 100, further comprising rehabilitating the debonded first semiconductor element prior to again directly bonding.

102. The method of claim 100, further comprising, after again directly bonding:
initially annealing the first semiconductor element if no critical bonding defect is detected;
directly bonding a second semiconductor element to the first semiconductor element after initially annealing; and
annealing the second semiconductor element and the first semiconductor element, wherein, during the annealing of the second semiconductor element and the first semiconductor element, dielectric bonds are formed between the second semiconductor element and the first semiconductor element without causing inelastic protrusion of conductive pads of the first semiconductor element, and wherein the conductive pads of the first semiconductor element do not expand beyond a dielectric layer of the first semiconductor element, the conductive pads disposed below a top surface of the dielectric layer in corresponding recesses, and wherein a temperature of annealing the second semiconductor element and the first semiconductor element is less than 85° C.

103. The method of claim 100, wherein detecting the bonding defect comprises inspecting the bond interface for bonding defects after directly bonding the first semiconductor element to the bonding site, wherein inspecting the bond interface is performed via optical inspection, and wherein the bonding defects comprise at least one of a bond void and a misalignment between the first semiconductor element and the bonding site.

104. The method of claim 100, further comprising cleaning the bonding site after debonding, wherein cleaning comprises applying an alkaline solution to the bonding site and vacuuming the bonding site.

105. The method of claim 104, further comprising:
initially annealing the first semiconductor element again after directly bonding;
directly bonding a second semiconductor element to the first semiconductor element after initially annealing; and
annealing the second semiconductor element and the first semiconductor element, wherein, during the annealing of the second semiconductor element and the first semiconductor element, dielectric bonds are formed between the second semiconductor element and the first semiconductor element without causing inelastic protrusion of conductive pads of the first semiconductor element, wherein the conductive pads of the first semiconductor element do not expand beyond a dielectric layer of the first semiconductor element, the conductive pads disposed below a top surface of the dielectric layer in corresponding recesses, and wherein a temperature of annealing the second semiconductor element and the first semiconductor element is less than 85° C.

106. The method of claim 100, wherein, after again directly bonding the first semiconductor element, bonding a second semiconductor element to the bonding site.

107. The method of claim 100, further comprising repeating a stacking of semiconductor elements until a desired number of semiconductor elements are stacked together and performing a final anneal to bond the stacked bonded structure, wherein a temperature of the final anneal is greater than 85° C.
